(19) United States
(12) Patent Application Publication
(10) Pub. No.: US 2025/0185419 A1
(43) Pub. Date: Jun. 5, 2025

(54) NITRIDE SEMICONDUCTOR LIGHT EMITTING DEVICE AND DISPLAY DEVICE HAVING THE SAME

(71) Applicant: SAMSUNG ELECTRONICS CO., LTD., Suwon-si (KR)

(72) Inventors: Jaegu Lim, Suwon-si (KR); Jonghyun Lee, Suwon-si (KR); Joongseo Kang, Suwon-si (KR); Namsung Kim, Suwon-si (KR); Minho Kim, Suwon-si (KR); Heonho Lee, Suwon-si (KR)

(73) Assignee: SAMSUNG ELECTRONICS CO., LTD., Suwon-si (KR)

(21) Appl. No.: 18/782,905

(22) Filed: Jul. 24, 2024

(30) Foreign Application Priority Data
Dec. 4, 2023 (KR) 10-2023-0173375
Feb. 8, 2024 (KR) 10-2024-0019896

(51) Int. Cl. H01L 33/12; H01L 25/075; H01L 25/16; H01L 33/06; H01L 33/32

(52) U.S. Cl. CPC H10H 20/815; H01L 25/0753; H01L 25/167; H10H 20/812; H10H 20/825

(57) ABSTRACT

A nitride semiconductor light-emitting device, including: a P-type nitride semiconductor layer; an N-type nitride semiconductor layer; an InGaN well layer between the P-type nitride semiconductor layer and the N-type nitride semiconductor layer; a barrier layer having a bandgap wider than the InGaN well layer; and a stress-relief layer between the barrier layer and the InGaN well layer, wherein the stress-relief layer includes a plurality of InN structures spaced apart from each other and distributed on the barrier layer. stress-relief.

### CROSS-REFERENCE TO RELATED APPLICATION(S)

This application is based on and claims priority under 35 USC 119(a) to Korean Patent Application No. 10-2023-0173375 filed on Dec. 4, 2023 and Korean Patent Application No. 10-2024-0019896 filed on Feb. 8, 2024 in the Korean Intellectual Property Office, the disclosures of which are incorporated by reference herein in their entireties.

### BACKGROUND

### 1. Field

The disclosure relates to a nitride semiconductor light-emitting device and a display device including the same.

### 2. Description of Related Art

Semiconductor light-emitting devices may be semiconductor devices configured to generate light having a specific wavelength through recombination of electrons and holes. Nitride semiconductor light-emitting devices may be configured to emit blue, green, and red light, and may be used as various light sources such as display devices as well as general lighting.

In nitride semiconductor light-emitting devices, the internal quantum efficiency may rapidly decrease as the wavelength increases. Accordingly, there is a need for a method of increasing internal quantum efficiency.

### SUMMARY

Provided is a nitride semiconductor light-emitting device that may emit long wavelength light with high efficiency.

Additional aspects will be set forth in part in the description which follows and, in part, will be apparent from the description, or may be learned by practice of the presented embodiments.

In accordance with an aspect of the disclosure, a nitride semiconductor light-emitting device includes: a P-type nitride semiconductor layer; an N-type nitride semiconductor layer; an InGaN well layer between the P-type nitride semiconductor layer and the N-type nitride semiconductor layer; a barrier layer having a bandgap wider than the InGaN well layer; and a stress-relief layer between the barrier layer and the InGaN well layer, wherein the stress-relief layer includes a plurality of InN structures spaced apart from each other and distributed on the barrier layer.

In accordance with an aspect of the disclosure, a nitride semiconductor light-emitting device includes: a P-type nitride semiconductor layer; an N-type nitride semiconductor layer; and an active layer between the P-type nitride semiconductor layer and the N-type nitride semiconductor layer, wherein the active layer includes: a plurality of GaN barrier layers; a plurality of InGaN well layers disposed between the plurality of GaN barrier layers; and a plurality of stress-relief layers disposed between the plurality of GaN barrier layers and the plurality of InGaN well layers, wherein the plurality of stress-relief layers include a plurality of InN structures distributed on the plurality of GaN barrier layers, and a plurality of InGaN intermediate layers between the plurality of InN structures on the plurality of GaN barrier layers, wherein an indium concentration of the plurality of InGaN intermediate layers is lower than an indium concentration of the plurality of InGaN well layers, and wherein a thickness of the plurality of InGaN intermediate layers is less than a thickness of the plurality of InGaN well layers.

In accordance with an aspect of the disclosure, a display device includes: a circuit board including a plurality of driving elements; and a pixel array disposed on the circuit board and including a plurality of light-emitting devices, wherein each light-emitting device from among the plurality of light-emitting devices includes: a P-type nitride semiconductor layer; an N-type nitride semiconductor layer; and an active layer between the P-type nitride semiconductor layer and the N-type nitride semiconductor layer, wherein the active layer includes a plurality of GaN barrier layers; a plurality of InGaN well layers disposed between the plurality of GaN barrier layers; and a plurality of stress-relief layers disposed between the plurality of GaN barrier layers and the plurality of InGaN well layers, wherein the plurality of stress-relief layers include a plurality of InN structures distributed on the plurality of GaN barrier layers and a plurality of InGaN intermediate layers between the plurality of InN structures on the plurality of GaN barrier layers, wherein an indium concentration of the plurality of InGaN intermediate layers is lower than an indium concentration the plurality of InGaN well layers, and wherein a thickness of the plurality of InGaN intermediate layers is less than a thickness of the plurality of InGaN well layers.

### BRIEF DESCRIPTION OF DRAWINGS

The above and other aspects, features, and advantages of the present disclosure will be more apparent from the following detailed description taken in conjunction with the accompanying drawings, in which:

FIG. 1 is a cross-sectional view of a nitride semiconductor light-emitting device according to embodiments;

FIG. 2A is a partially enlarged view of portion “A” of FIG. 1, and FIG. 2B is a top view of a stress-relief layer of FIG. 1, according to embodiments;

FIG. 3 is a graph illustrating a change in bandgap in a stacking direction in a P-type nitride semiconductor layer of the nitride semiconductor light-emitting device illustrated in FIG. 1, according to embodiments;

FIG. 4 is a cross-sectional view of a nitride semiconductor light-emitting device according to embodiments;

FIG. 5A is a cross-sectional view of a nitride semiconductor light-emitting device according to example embodiments, and FIG. 5B is a partially enlarged view illustrating portion “B” of FIG. 5A, according to embodiments;

FIG. 6 is a partially enlarged view of a nitride semiconductor light-emitting device of another embodiment applicable to portion “B” of FIG. 5A, according to embodiments;

FIG. 7 is a partially enlarged view of a nitride semiconductor light-emitting device of another embodiment applicable to portion “B” of FIG. 5A, according to embodiments;

FIG. 8A is a side cross-sectional view of a nitride semiconductor light-emitting device according to another embodiment, and FIG. 8B is a partially enlarged view illustrating portion “C” of FIG. 8A, according to embodiments;

FIG. 9 is a graph illustrating wavelength and internal quantum efficiency of a nitride semiconductor light-emitting device according to embodiments;

FIG. 10 is a schematic perspective view of a display device according to embodiments;

FIG. 11 is a partially enlarged view illustrating portion “D” of the display device illustrated in FIG. 10, according to embodiments;

FIG. 12 is a side cross-sectional view illustrating a display device according to embodiments;

FIG. 13 is a driving circuit implemented by a display device according to embodiments;

FIG. 14 is a cross-sectional view illustrating a display device according to embodiments; and

FIG. 15 is a schematic diagram of an electronic device including a display device according to embodiments.

### DETAILED DESCRIPTION

Hereinafter, example embodiments are described with reference to the accompanying drawings.

As is traditional in the field, the embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the present scope. Further, the blocks, units and/or modules of the embodiments may be physically combined into more complex blocks, units and/or modules without departing from the present scope.

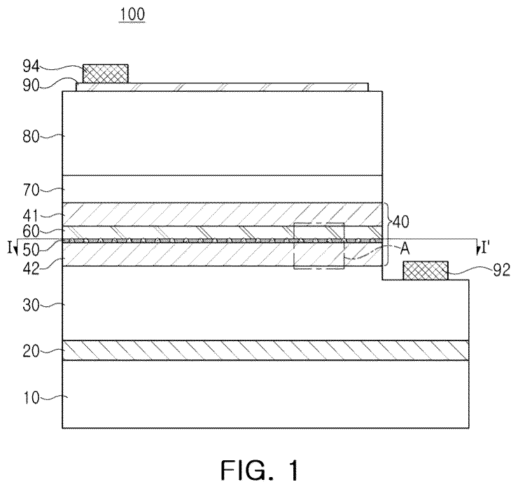

FIG. 1 is a cross-sectional view illustrating a nitride semiconductor light-emitting device according to example embodiments.

A nitride semiconductor light-emitting device 100 according to this embodiment may include a substrate 10, a first conductivity-type nitride semiconductor layer 30, an active layer 40, and a second conductivity-type nitride semiconductor layer 80 sequentially disposed on the substrate 10.

According to embodiments, a buffer layer 20 may be disposed between the substrate 10 and the first conductivity-type nitride semiconductor layer 30. The substrate 10 according to embodiments may be an insulating substrate such as sapphire. In some embodiments, buffer layer 20 may be or may include InₓAl_{y}Ga_{1-x-y}N (where 0≤x≤1, 0≤y≤1). For example, the buffer layer 20 may be or may include AlN, AlGaN, or InGaN. In some embodiments, the buffer layer 20 may include a plurality of layers with different compositions, or may include a layer having a composition (for example, Al or In) which is gradually changed.

The first conductivity-type nitride semiconductor layer 30 may be a nitride semiconductor layer which may include N-type InₓAl_{y}Ga_{1-x-y}N (where 0≤x≤1, 0≤y≤1, 0≤x+y≤1), and the N-type impurity may be Si. For example, the first conductivity-type nitride semiconductor layer 30 may include N-type GaN. Similarly, the second conductivity-type nitride semiconductor layer 80 may be a nitride semiconductor layer which may include P-type InₓAl_{y}Ga_{1-x-y}N (where 0≤x≤1, 0≤y≤1, 0≤x+y≤1), and the P-type impurity may be Mg. For example, in some embodiments the second conductivity-type nitride semiconductor layer 80 may be implemented as a single-layer structure, but embodiments are not limited thereto, and in some embodiments the second conductivity-type nitride semiconductor layer 80 may have a multi-layer structure with different compositions. For example, the second conductivity-type nitride semiconductor layer 80 may include a low-concentration P-type GaN layer and a high-concentration P-type GaN layer. In this case, a P-type electrode 94 may be formed on the highly concentrated P-type GaN layer.

According to embodiments, an electron blocking layer 70 may be disposed between the second conductivity-type nitride semiconductor layer 80 and the active layer 40. The electron blocking layer 70 may have a band gap (or energy band gap) larger than a band gap (or energy band gap) of the active layer 40 and the adjacent layer, and may include a nitride single crystal layer represented by Al_{y}Ga_{(1-y)}N. For example, the electron blocking layer 70 may be configured so that the band gap decreases as the distance increases. This grading or gradation of the band gap may be implemented by adjusting the Al composition ratio. As an example, the electron blocking layer 70 may have a thickness of 5 nm to 100 nm.

The active layer 40 may have a multilayer structure including a well layer 60, a barrier layer 41, and a barrier layer 42. A band gap of the barrier layers 41 and 42 may be larger than a band gap of the well layer 60. The active layer 40 according to embodiments may be configured to emit light having a relatively long wavelength (for example, in a range from 500 nanometers (nm) to 650 nm). Long-wavelength light may refer to green light (for example, light having a wavelength in a range from 500 nm to 590 nm), orange light (for example, light having a wavelength in a range from 590 nm to 620 nm), and red light (for example, light having a wavelength in a range from 620 nm to 650 nm).

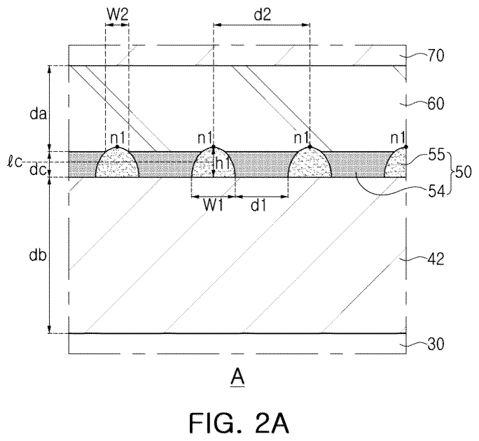

According to embodiments, the well layer 60 may include a nitride single crystal which may be represented by Inₓ₁Ga₁₋ₓ₁N. In embodiments, x1 may denote a first indium composition ratio, which may be in a range of 0.3 to 0.5, and the thickness da (as shown for example in FIG. 2A) of the well layer 60 may be in a range of 2 nm to 5 nm. The barrier layers 41 and 42 may include a nitride single crystal which may be represented by InₐGa₁₋ₐN (where 0≤a≤0.2). For example, the barrier layers 41 and 42 may include GaN. In some embodiments, the barrier layers 41 and 42 may include GaN doped with an N-type impurity such as Si. For example, the Si doping concentration may be in a range of 1×10¹⁷/cm² to 1×10¹⁹/cm², and the thickness db (as shown for example in FIG. 2A) of the barrier layers 41 and 42 may be in a range of 5 nm to 20 nm.

The active layer 40 according to embodiments may have a unique structure of the light-emitting layer including the well layer 60. As illustrated in FIG. 1, the active layer 40 may include a stress-relief layer 50 between the well layer 60 and the barrier layer 42.

The well layer 60 may have a relatively high indium composition ratio, but when the well layer 60 is formed with a relatively large thickness and multiple layers during a growth process, excessive stress may be transmitted and the degree of change in indium composition may intensify, which may result in an imbalance that creates deep regions (e.g., deep local states) where the band gap is locally reduced. Such deep regions may cause crystallographic defects and may cause non-luminous coupling factors within the well layer 60, which may cause a decrease in internal quantum efficiency. To prevent this, embodiments may include a stress-relief layer 50 between the barrier layer 42 and the well layer 60 stacked thereon. The stress-relief layer 50 may include InN structures 55 which may have a high concentration of indium and may be spaced apart from each other, and the stress-relief layer 50 may further include an intermediate layer 54 for lattice buffering between the well layer 60 and the barrier layers 41 and 42 while simultaneously fixing a plurality of InN structures 55.

Each of the high-concentration InN structures 55 may be implemented in an island type or island configuration, which may mean that each high-concentration InN structure 55 is not connected to or directly in contact with neighboring high-concentration InN structures 55. The high-concentration InN structures 55 disposed on the barrier layer 42 may have a similar range of sizes and may be uniformly distributed. In this case, ‘uniformly distributed’ is not necessarily intended to mean that the arrangement is has regularity, and instead may mean that the size of each high-concentration InN structure 55, for example, the diameter W1 and height h1, may be substantially the same and may be included in a similar size range. The high-concentration InN structures 55 may be grown as InN by injecting high-concentration indium-containing gas and ammonia within a predetermined temperature range on the barrier layer 42. Then, growth may be performed at a temperature of 650 degrees Celsius or lower, which may be lower than the temperature at which crystals grow to form a high-concentration InN layer, so that the growing crystals may not form a layer. Each of the high-concentration InN structures 55 may have a high density, and small island-shaped high-concentration InN structures 55 may therefore be formed. When these island-shaped, high-concentration InN structures 55 are uniformly distributed throughout the barrier layer 42 and the upper well layer 60 is formed of thick Inₓ₁Ga₁₋ₓ₁N, local imbalance in indium composition may be offset. For each of the high-concentration InN structures 55, as illustrated in FIGS. 2A and 2B, when viewed in cross section perpendicular to the upper surface of the substrate 10 in the stacking direction, the cross section may have a partial oval shape, or for example a half oval shape, which may be a half-ellipse having a first diameter W1 at the bottom which may be equal to or greater than a height h1.

Accordingly, the three-dimensional shape of the high-concentration InN structures 55 may have the shape of a dome and may be part of a sphere. The first diameter W1 of each high-concentration InN structure 55 may be in a range from 0.5 nm to 1.0 nm, and the height h1 may be equal to or smaller than the first diameter W1, and may be in a range of about 0.3 nm to about 0.5 nm. In addition, a first separation distance d1 between lower ends of two neighboring high-concentration InN structures 55 may be in a similar range, and may be for example 1 to 1.5 times the first diameter W1 as a minimum separation distance. When the first separation distance d1 is smaller than the minimum separation distance, neighboring high-concentration InN structures 55 may be connected to each other and may grow to form a large structure, and this may act as a defect and may therefore reduce internal quantum efficiency. Accordingly, the size of the high-concentration InN structures 55 may be maintained within a predetermined range by spacing them apart from each other so that the first separation distance d1 is within a range of 1 to 1.5 times the first diameter W1, which may be the minimum separation distance. Accordingly, the plurality of island-shaped high-concentration InN structures 55 grown on the barrier layer 42 and distributed uniformly may be dispersed in the stress-relief layer 50 having a density of 1.6e¹⁷ to 3.2e¹⁷ pieces/cm², when viewed as a whole.

The stress-relief layer 50 may further include an intermediate layer 54 that may be disposed on a barrier layer which is exposed between the plurality of high-concentration InN structures 55, and may also fix or otherwise hold the plurality of high-concentration InN structures 55. The intermediate layer 54 may include a nitride single crystal represented by Inₓ₂Ga₁₋ₓ₂N, and the second indium composition ratio x2 may be at a relatively low concentration, for example within a range of 0 to 0.1. As an example, the intermediate layer 54 may be GaN, and in this case, the second indium composition ratio x2 may be substantially 0.

The intermediate layer 54 may have an indium composition ratio that is equal to or greater than that of the barrier layer 42 and is smaller than that of the well layer 60, and may have an intermediate lattice that is larger than the lattice of the well layer 60, which may be InGaN, and smaller than the lattice of the barrier layer 42, which may be GaN, and therefore may have a lattice relaxation function. In addition, the intermediate layer 54 may be formed on the barrier layer 42 on which the plurality of island-like high-concentration InN structures 55 may be grown to simultaneously fix or hold the plurality of island-like high-concentration InN structures 55, and during the subsequent high-temperature process for forming the well layer 60, indium may be prevented from volatilizing from the surface of the plurality of island-type high-concentration InN structures 55. To this end, the intermediate layer 54 may have a thickness dc equal to or smaller than the height h1 of the plurality of island-like high-concentration InN structures 55. When defining the midpoint of the height h1 of the plurality of island-type high-concentration InN structures 55 as the virtual center line lc, the upper surface of the intermediate layer 54 may be located on a level higher than the virtual center line lc.

According to embodiments, the upper surface of the intermediate layer 54 may have different levels depending on the concentration of indium in the intermediate layer 54. For example, the lower the concentration of indium in the intermediate layer 54, the higher the upper surface of the intermediate layer 54 may be, but the upper surface may not be higher than the highest point n1 of the plurality of island-like high-concentration InN structures 55. For example, a maximum thickness dc of the intermediate layer 54 may be equal to the height h1 of the plurality of island-type high-concentration InN structures 55. FIG. 2A illustrates an example in which the indium concentration of the intermediate layer 54 is not 0 (e.g., an example in which the second indium composition ratio x2 is greater than 0 and less than 0.1). The upper surface of the intermediate layer 54 may be located at a level that is lower than a level of the highest point n1 of the plurality of island-like high-concentration InN structures 55, and higher than a level of the virtual center line lc. As an example, the intermediate layer 54 may have a thickness dc of ⅔ to ⅘ of the height h1 of the plurality of island-like high-concentration InN structures 55. When the height h1 of the plurality of island-like high-concentration InN structures 55 is in the range of 0.3 nm to 0.5 nm, the thickness dc of the intermediate layer 54 may be in a range of at least 0.15 nm to 0.5 nm, which may be the same as or similar to the thickness range of the stress-relief layer 50.

Accordingly, the stress-relief layer 50 may include portions of a plurality of island-like high-concentration InN structures 55 protruding above the intermediate layer 54, and may have an embossing or an embossed appearance when viewed in a plan view, as illustrated in FIG. 2B. A portion of the island-like high-concentration InN structures 55 protruding above the upper surface of the intermediate layer 54 may be a spherical portion having an upper width W2 smaller than the first diameter W1 at the level of the upper surface of the intermediate layer 54. Accordingly, the second separation distance d2 of the upper portions of the island-type high concentration InN structures 55 at the level of the upper surface of the intermediate layer 54 may be larger than the first separation distance d1.

The well layer 60 may be disposed on the upper surface of the stress-relief layer 50, for example, on the intermediate layer 54 on which the embossing is formed. Accordingly, a portion of the island-like high-concentration InN structures 55 may have a structure that protrudes into the well layer 60. In this manner, when the island-like high-concentration InN structures 55 protrude into the well layer 60, the regional imbalance in indium concentration caused by the well layer 60 being formed in multiple layers or the well layer 60 being formed to be relatively thick may be offset, and may function as a well layer 60 with an overall uniform indium concentration.

The barrier layers 41 and 42 may have a thickness db in a range of 5.0 nm to 20.0 nm, and the well layer 60 may have a thickness da smaller than this, for example, in a range of 2.0 nm to 5.0 nm. The stress-relief layer 50 between the barrier layers 41 and 42 and the well layer 60 may have a thickness dc in a range of 0.15 nm to 0.5 nm, which may be similar to the thickness dc of the intermediate layer 54.

Examples of bandgap characteristics of the semiconductor light-emitting device 100 according to the embodiment illustrated in FIGS. 1 to 2B are described below.

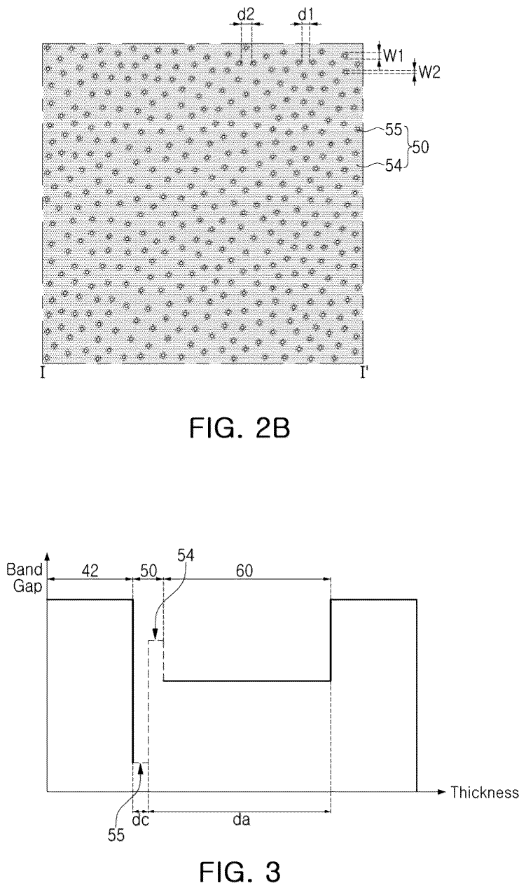

As illustrated in FIG. 3, the InGaN layer having a small band gap may function as a well layer 60 between the barrier layers 42 having a large band gap. In order to function as the well layer 60, an indium composition and a thickness of a critical value (e.g., in a range of 1 nm to 1.5 nm) or more may be required. If the thickness of the critical value or more is not satisfied, no photons may be generated and no emission peak may be generated, which may prevent the proper functioning of the light-emitting layer.

Referring to FIG. 3, the semiconductor light-emitting device 100 according to example embodiments may be arranged so that the stress-relief layer 50 has a relatively very small thickness dc compared to the well layer 60. The stress-relief layer 50 may be created to be a very thin compared to the well layer 60, with a thickness dc of, for example, less than 1 nm, or a thickness dc of, for example, 0.5 nm or less. Accordingly, the stress-relief layer 50 may not function as a well layer because the high-concentration InN structures 55 may have a higher indium composition than the barrier layer 42, but may not form an emission peak (indicated in FIG. 3 by a dotted line), and may not function as a light-emitting layer with a separate wavelength, but may perform lattice relaxation and indium composition compensation functions.

Therefore, the semiconductor light-emitting device 100 according to example embodiments may further include a relatively very thin stress-relief layer 50 that may not function as a well layer between the barrier layer 42 and the well layer 60, and when the local imbalance in the indium composition is resolved thereby, the wavelength of the red light generated in the well layer 60 may be shifted to a longer wavelength, for example, shifted 40 nm or more, and thus, more reddish light may be emitted. Additionally, because defects may be avoided by lattice buffering, internal photon efficiency may be improved.

Referring again to FIG. 1, the nitride semiconductor light-emitting device 100 according to this embodiment may include a first electrode 92 disposed on the first conductivity-type nitride semiconductor layer 30, and an ohmic contact layer 90 and second electrode 94 sequentially disposed on the second conductivity-type nitride semiconductor layer 80.

The ohmic contact layer 90 may have a single-layer or dual-layer or more structure. The ohmic contact layer 90 may be implemented in various ways depending on the chip structure. For example, when the nitride semiconductor light-emitting device 100 has a flip chip structure (for example, a structure in which light is emitted in the direction of the substrate 10), the ohmic contact layer 90 may include a reflective metal layer. For example, the reflective metal layer may include Ag, Ni, Al, Rh, Pd, Ir, Ru, Mg, Zn, Pt, and Au. In a some embodiments, the ohmic contact layer 90 may further include a light-transmitting electrode for distributing current between the reflective metal layer and the second conductivity-type nitride semiconductor layer 80.

As another example, when the nitride semiconductor light-emitting device 100 has a structure in which light is emitted in a direction opposite to the substrate 10, the ohmic contact layer 90 may include a light-transmitting electrode. The light-transmitting electrode may be a transparent conductive oxide layer or nitride layer. The light-emitting electrode may be at least one from among, for example, Indium Tin Oxide (ITO), Zinc-doped Indium Tin Oxide (ZITO), Zinc Indium Oxide (ZIO), Gallium Indium Oxide (GIO), Zinc Tin Oxide (ZTO), Fluorine-doped Tin Oxide (FTO), Aluminium-doped Zinc Oxide (AZO), Gallium-doped Zinc Oxide (GZO), In₄Sn₃O₁₂ and Zn₍₁₋ₓ₎MgₓO (Zinc Magnesium Oxide, 0≤x≤1). In some embodiments, the ohmic contact layer 90 may include graphene.

For example, the first electrode 92 may include Ag, Ni, Al, Rh, Pd, Ir, Ru, Mg, Zn, Pt, and Au, similar to the ohmic contact layer 90, and may have a single-layer or dual-layer or more structure. In some embodiments, the first electrode 92 may include Cr/Au. The second electrode 94 may be a pad electrode located in a partial area of the ohmic contact layer 90. For example, the second electrode 94 may include Au, Sn, or Au/Sn. A pad electrode such as Au, Sn, or Au/Sn may also be disposed on the first electrode 92.

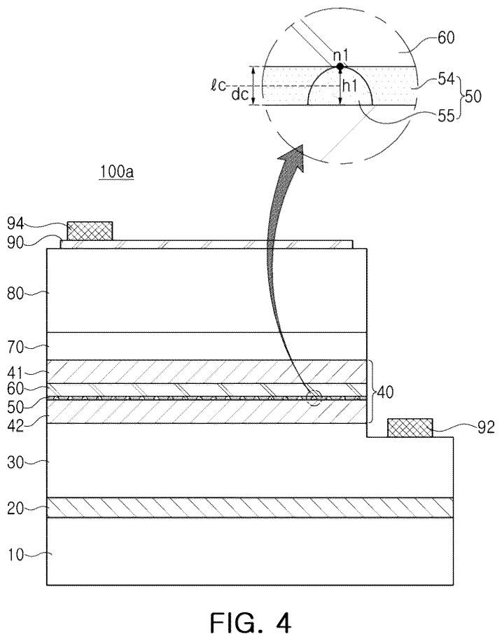

Hereinafter, examples of various embodiments will be described with reference to FIGS. 4 to 8B.

Referring to FIG. 4, a nitride semiconductor light-emitting device 100a according to this embodiment may be substantially similar to the embodiment of FIGS. 1 to 2B except that the thickness dc may change depending on the composition of the intermediate layer 54 of the stress-relief layer 50.

The nitride semiconductor light-emitting device 100a of FIG. 4 may include a stress-relief layer 50 between a barrier layer 42 and a well layer 60 stacked thereon, and the stress-relief layer 50 may include a plurality of island-type InN structures 55 and an intermediate layer 54 for lattice buffering between the well layer 60 and the barrier layer 42 while simultaneously fixing or holding the plurality of island-type InN structures 55.

The high-concentration InN structures 55 may be each implemented as an island type, and may be not connected to or directly contacting the neighboring high-concentration InN structures 55, and the shape, size, and uniform distribution thereof may be the same as or similar to those in FIGS. 1 to 2B.

When these island-shaped, high-concentration InN structures 55 are uniformly distributed throughout the barrier layer 42, and when the well layer 60 formed at the top is formed of Inₓ₁Ga₁₋ₓN having a thick high concentration of indium, local imbalance in indium composition may be resolved.

For example, the first diameter W1 of each high-concentration InN structure 55 may be in a range of 0.5 nm to 1.0 nm, and the height h1 may be equal to or smaller than the diameter and in a range of about 0.3 nm to 0.5 nm. In embodiments, the first separation distance d1 between two neighboring high-concentration InN structures 55 may be within a similar range, and the minimum separation distance may be 1 to 1.5 times the first diameter W1.

In the example shown in FIG. 4, the intermediate layer 54 may include a nitride single crystal containing GaN and not containing indium, and the intermediate layer 54 may have the same indium concentration as the barrier layer 42, but the island-shaped, high-concentration InN structures 55 may be dispersed inside, thereby providing a stress-relief effect. After a plurality of island-type high-concentration InN structures 55 are formed on the barrier layer 42, when the same GaN as the barrier layer 42 is deposited as the intermediate layer 54 that fixes or holds the plurality of island-type high-concentration InN structures 55, a gas containing indium may be not introduced as the deposition gas, and the deposition temperature may not reach a temperature at which indium volatilizes from the surface of the high-concentration InN structures 55. However, if a deposition gas containing high concentration indium is injected and growth proceeds at a high temperature in forming the well layer 60, indium may diffuse from the exposed area and flow into the well layer 60 when the high-concentration InN structures 55 are exposed above the intermediate layer 54. Such inflow of indium into the well layer 60 may accelerate local irregularities in the indium composition within the well layer 60. Therefore, when GaN material having a second indium composition ratio x2 of 0 is applied as the intermediate layer 54, the height dc of the intermediate layer 54 and the height h1 of the high-concentration InN structures 55 may be substantially the same in order to cover all of the high-concentration InN structures 55.

However, when overdeposited so that the upper surface of the intermediate layer 54 is located on a level higher than the highest point n1 of the high-concentration InN structures 55, the function of offsetting regional imbalances in the indium composition of the well layer 60 may be reduced. Accordingly, the intermediate layer 54 may be deposited to a height that is equal to or equivalent to the height h1 of the plurality of island-like high-concentration InN structures 55, or to a height that is substantially the same. For example, the upper surface of the intermediate layer 54 may be located at a level in a range of 10% of the total height h1 with respect to the highest point n1 of the height h1 of the plurality of island-like high-concentration InN structures 55.

Therefore, when viewed from above the intermediate layer 54, the high-concentration InN structures 55 may not be observed, or may be observed in the form of relatively very small dots. Due to this minimal exposure, diffusion of indium into the well layer 60 may be minimized or prevented.

The barrier layer 42 may have a thickness db of 5.0 to 20.0 nm, and the well layer 60 may have a thickness da smaller than this, for example, a thickness da of 2.0 to 5.0 nm. The stress-relief layer 50 between the barrier layer 42 and the well layer 60 may have a thickness dc of 0.3 to 0.5 nm, which may be the height h1 of the high-concentration InN structures 55.

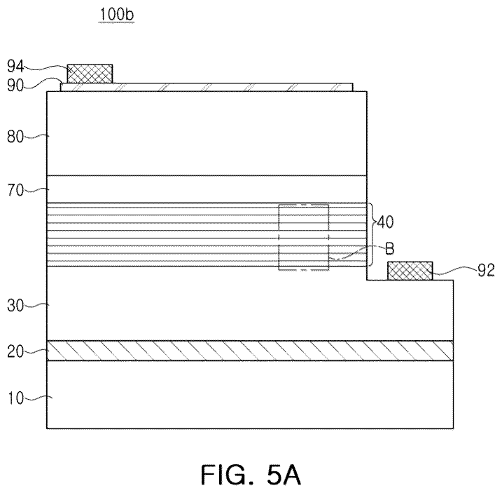

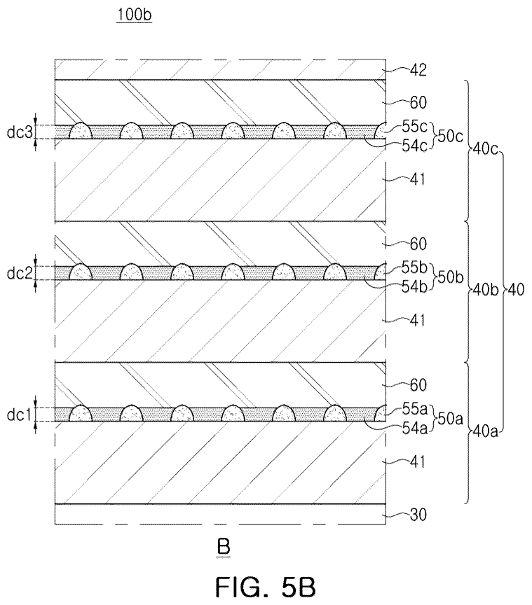

FIG. 5A is a side cross-sectional view of a nitride semiconductor light-emitting device according to example embodiments, and FIG. 5B is a partially enlarged view illustrating portion “B” of FIG. 5A.

Referring to FIGS. 5A and 5B, a nitride semiconductor light-emitting device 100b according to example embodiments may include a plurality of subactive layers 40a-40c in which the active layer 40 intersects a plurality of well layers 60 and a plurality of barrier layers 42. The plurality of subactive layers 40a-40c may include a multi-layer structure including a barrier layer 42, a stress-relief layer 50a-50c, and a well layer 60. FIGS. 5A to 5B illustrate an example in which the active layer 40 includes three subactive layers 40a-40c, but embodiments are not limited thereto, and the number of subactive layers 40a-40c may be any desired number, for example two to five. Each of the subactive layers 40a-40c may generate and emit red light having a specific wavelength depending on the indium composition of the well layers 60, which may be light-emitting layers, and within one semiconductor light-emitting device 100b, the emission light from each light-emitting layer may be synthesized to emit synthesized red light.

Referring to FIG. 5B, each barrier layer 42 within the subactive layers 40a-40c may have a stacked structure of first subactive layers 40a, second subactive layers 40b, and third subactive layers 40c in a direction away from the upper surface of the first conductivity-type nitride semiconductor layer 30, and an upper barrier layer 41 may be further disposed on the well layer 60 of the third subactive layers 40c.

The first subactive layer 40a, the second subactive layer 40b, and the third subactive layer 40c may all include the same barrier layer 42 and the same well layer 60, which may be substantially the same as the configuration of the barrier layer 42 and the well layer 60 in FIGS. 1 to 2B.

Additionally, the stress-relief layers 50a-50c of the first to third subactive layers 40a-40c may all have the same or similar structure. For example, the first stress-relief layer 50a of the first subactive layer 40a, the second stress-relief layer 50b of the second subactive layer 40b, and the third stress-relief layer 50c of the third subactive layer 40c may have the same structure as the stress-relief layer 50 of FIGS. 1 to 2B. For example, high-concentration InN structures 55a-55c may be formed dispersed in an island shape on the lower GaN barrier layer 42, and the intermediate layers 54a-54c may be disposed on the barrier layer 42 while simultaneously fixing the high-concentration InN structures 55a-55c. The intermediate layers 54a-54c may include a nitride single crystal represented by Inₓ₂Ga₁₋ₓ₂N, and the second indium composition ratio x2 may be at a relatively low concentration, for example a concentration in a range of 0 to 0.1. If the second indium composition ratio x2 is not 0, the upper surface of the intermediate layer (54a-54c) may be located on a level between the virtual center line lc and the highest point n1 of the height of the high-concentration InN structures 55a-55c. However, in some embodiments, as illustrated in FIG. 4, when the intermediate layers 54a-54c include GaN with a second indium composition ratio x2 of 0, the upper surfaces of the intermediate layers 54a-54c may be located at substantially the same level as the height h1 of the high-concentration InN structures 55.

According to embodiments, the indium compositions of the well layers 60 of the subactive layers 40a-40c may be different from each other, but embodiments are not limited thereto.

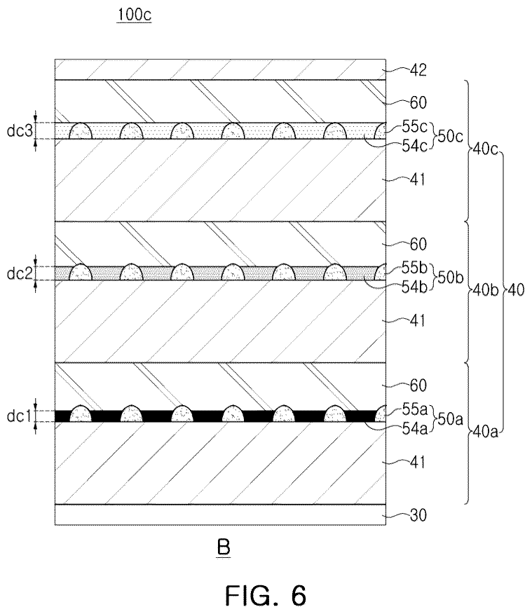

Referring to FIG. 6, a nitride semiconductor light-emitting device 100c according to example embodiments may include a plurality of subactive layers 40a-40c in which the active layer 40 intersects a plurality of well layers 60 and a plurality of barrier layers 42. The plurality of subactive layers 40a-40c may include a multi-layer structure including a barrier layer 42, a stress-relief layer 50a-50c, and a well layer 60, and may be the same as or similar to the example shown in FIGS. 5A and 5B except that the first to third stress-relief layers 50a-50c of the first to third subactive layers 40a-40c may be different from each other.

In detail, the first subactive layer 40a, the second subactive layer 40b, and the third subactive layer 40c may all include the same barrier layer 42 and the same well layer 60, which may be the same as or similar to the configuration of the barrier layer 42 and the well layer 60 in FIGS. 1 to 2B.

The first stress-relief layer 50a of the first subactive layer 40a, the second stress-relief layer 50a of the second subactive layer 40b, and the third stress-relief layer 50a of the third subactive layer 40c. As the distance from the upper surface of the first conductivity-type nitride semiconductor layer 30 increases, the indium composition of the intermediate layer 54 may decrease. When the intermediate layer 54 includes a nitride single crystal represented by Inₓ₂Ga₁₋ₓ₂N, the first stress-relief layer 50a has a second indium composition ratio x2 of 0.05 to 0.1, and the second stress-relief layer 50b includes a second indium composition ratio x2 that is lower than the second indium composition ratio x2 of the first stress-relief layer 50, and may satisfy, for example, 0.02 to 0.04. In addition, the third stress-relief layer 50c may have a second indium composition ratio x2 lower than the second indium composition ratio x2 of the second stress-relief layer 50b, and may include, for example, a GaN material having a second indium composition ratio of substantially 0.

According to embodiments, the high-concentration InN structures 55a-55c of the first to third stress-relief layers 50a-50c may all have the same or similar shape, and the shape, size, and uniform distribution thereof may all be the same as or similar to those described in FIGS. 1 to 2B.

Therefore, when the height h1 of the high-concentration InN structures 55a-55c is in the range of 0.3 to 0.5 nm, the thicknesses dc1, dc2 and dc3 of respective intermediate layers 54a-54c of the first to third stress-relief layers 50a-50c may be different from each other depending on the indium composition of the intermediate layer 54.

For example, as the second indium composition ratio x2 of the intermediate layer 54 decreases, the thickness dc may become greater. Therefore, as the distance from the upper surface of the first conductivity-type nitride semiconductor layer 30 increases, the second indium composition ratio x2 of the intermediate layers 54a-54c decreases, and the intermediate layer 54 may include stress-relief layers 50a-50c having large thicknesses dc1-dc3.

As shown in FIG. 6, the thickness dc3 of the intermediate layer 54c of the uppermost third subactive layer 40c may be the largest, and the thickness dc1 of the intermediate layer 54a of the lowermost first subactive layer 40a may be the smallest. Because the upper surface of the intermediate layer 54a of the lowermost first subactive layer 40a may be located on a level higher than the virtual center line lc of the height h1 of the high-concentration InN structures 55, the upper surface may not be located at the same level or lower than the imaginary center line lc. For example, the thickness dca of the intermediate layer 54a may be ½ or more of the height h1 of the high-concentration InN structures 55a. In addition, the thickness dc3 of the intermediate layer 54c of the uppermost third subactive layer 40c may not be greater than the height h1 of the high-concentration InN structures 55c, and may have the thickness dc3 substantially equal to the height h1 of the high-concentration InN structures 55c.

The thickness dc2 of the intermediate layer 54b of the second subactive layer 40b may have a thickness between the thickness dc1 of the first subactive layer 40a and the thickness dc3 of the intermediate layer 54c of the third subactive layer 40c. Accordingly, the size of the high-concentration InN structures 55a-55c exposed on the first to third stress-relief layers 50a-50c in the first to third subactive layers 40a-40c may be smaller as the distance from the upper surface of the first conductivity-type nitride semiconductor layer 30 increases.

This may be because the stress-relief layer 50a at the bottom may receive the most stress. To compensate for stress, an intermediate layer 54 with a relatively large indium composition may be applied, but as the need for stress compensation decreases toward the top, because the function of removing local imbalances in the indium composition of the well layer 60 is further required, the thickness and composition may be adjusted accordingly.

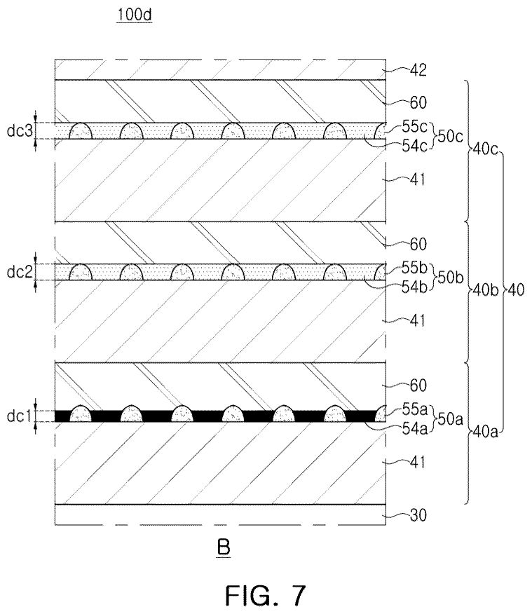

Referring to FIG. 7, a nitride semiconductor light-emitting device 100d according to example embodiments may include a plurality of subactive layers 40a-40c in which the active layer 40 intersects a plurality of well layers 60 and a plurality of barrier layers 42. The plurality of subactive layers 40a-40c may include a multi-layer structure including a barrier layer 42, a stress-relief layer 50a-50c, and a well layer 60, and may be the same as or similar to the example shown in FIG. 6 except that the first to third stress-relief layers 50a-50c of the first to third subactive layers 40a-40c are partially different.

In detail, the first subactive layer 40a, the second subactive layer 40b, and the third subactive layer 40c all include the same barrier layer 42 and the same well layer 60, which may be the same as or similar to the configuration of the barrier layer 42 and the well layer 60 in FIGS. 1 to 2B.

According to embodiments, the high-concentration InN structures 55a-55c of the first to third stress-relief layers 50a-50c may all have the same or similar shape, and the shape, size, and uniform distribution thereof may all be the same as or similar to those described in FIGS. 1 to 2B.

Among the first stress-relief layer 50a of the first subactive layer 40a, the second stress-relief layer 50b of the second subactive layer 40b, and the third stress-relief layer 50c of the third subactive layer 40c, only the intermediate layer 54a of the first stress-relief layer 50a, which may be the lowermost layer, may have a second indium composition ratio x2 in a range of 0.01 to 0.1, and the intermediate layers 54c of the second stress-relief layer 50b and the third stress-relief layer 50c may all include a GaN material having a second indium composition ratio x2 of substantially 0.

According to embodiments, the high-concentration InN structures 55a of the first to third stress-relief layers 50a-50c may all have the same or similar shape, and the shape, size, and uniform distribution thereof may all be the same as or similar to those described in FIGS. 1 to 2B.

Therefore, when the height h1 of the high-concentration InN structures 55a-55c is in a range of 0.3 nm to 0.5 nm, the thickness dc1 of the intermediate layer 54a of the first stress-relief layer 50a may be smaller than the thickness dc2, dc3 of the intermediate layers 54b and 54c of the second and third stress-relief layers 50b and 50c. However, the upper surface of the intermediate layer 54a of the first stress-relief layer 50a may be higher than the virtual center line lc of the height h1 of the high-concentration InN structures 55a, and thus, the stress-relief layer 50a may not be placed at the same or lower level as the virtual center line lc. For example, the thickness dc1 of the intermediate layer 54a may be at least ½ and less than 1 times the height h1 of the high-concentration InN structures 55a. However, the thicknesses dc2 and dc3 of the intermediate layers 54b and 54c of the second and third stress-relief layers 50b and 50c may be substantially the same as each other, and thus, may be not greater than the height h1 of the high-concentration InN structures 55b and 55c, and the thicknesses dc2 and dc3 may be substantially equal to the height h1 of the high-concentration InN structures 55b and 55c.

Accordingly, high-concentration InN structures 55a exposed only on the first stress-relief layer 50a may be observed within the first to third subactive layers 40a-40c, and some of the high-concentration InN structures 55b and 55c may not be substantially observed above the second and third stress-relief layers 50b and 50c.

The stress-relief layer 50a at the bottom receives the most stress. To compensate for the stress, an intermediate layer 54 having a relatively large indium composition may be applied. As the need for stress compensation decreases toward the top, because the function of offsetting regional imbalances in the indium composition of the well layer 60 is further required, the thickness and composition may be set accordingly.

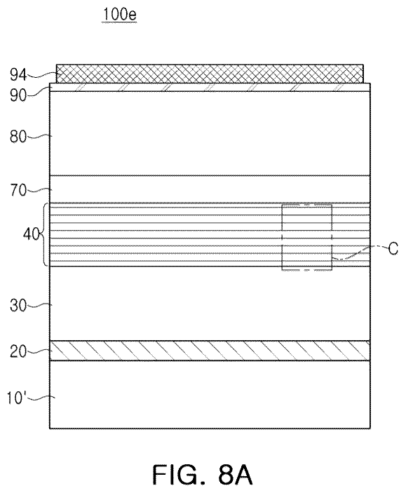

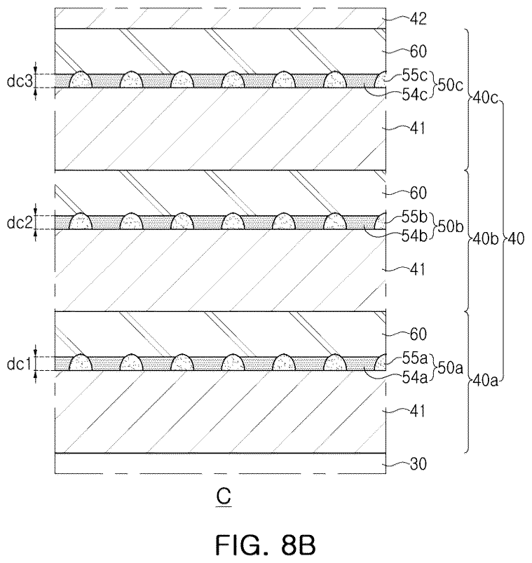

FIG. 8A is a side cross-sectional view of a nitride semiconductor light-emitting device according to another embodiment, and FIG. 8B is a partially enlarged view illustrating portion “C” of FIG. 8A.

Referring to FIGS. 8A and 8B, a nitride semiconductor light-emitting device 100e may include a conductive substrate 10′, a buffer layer 20, a first conductivity-type nitride semiconductor layer 30, an active layer 40, and a second conductivity-type nitride semiconductor layer 80. The conductive substrate 10′ according to embodiments may be or may include silicon (Si), SiC, or GaN, and may be a substrate doped with a first conductivity-type impurity (e.g., an N-type impurity). For example, the conductive substrate 10′ may be a silicon substrate used as a growth substrate.

The conductive substrate 10′ may be used as part of the one-side electrode structure. For example, the electrode 94 disposed on the conductive substrate 10′ and the second conductivity-type nitride semiconductor layer 80 may be used as both electrodes for a nitride semiconductor light-emitting device. Using this electrode arrangement, current flow may be implemented in a vertical direction.

The active layer 40 may have a multilayer structure including a well layer 60 and a barrier layer 42 having a band gap greater than the band gap of the well layer 60. The well layer 60 may include a nitride single crystal represented by Inₓ₁Ga₁₋ₓ₁N, and the first indium composition ratio x1 may be 0.3 to 0.5. The barrier layer 42 may include a nitride single crystal represented by InₐGa₁₋ₐN (0≤a≤0.2). For example, the barrier layer 42 may include GaN. In some embodiments, the barrier layer 42 may include GaN doped with an N-type impurity such as Si.

The active layer 40 according to embodiments may include a plurality of subactive layers 40a-40c, similar to the previous embodiments of FIGS. 5A to 7. Each subactive layer 40a-40c may include a stress-relief layer 50a-50c between the well layer 60 and the barrier layer 42.

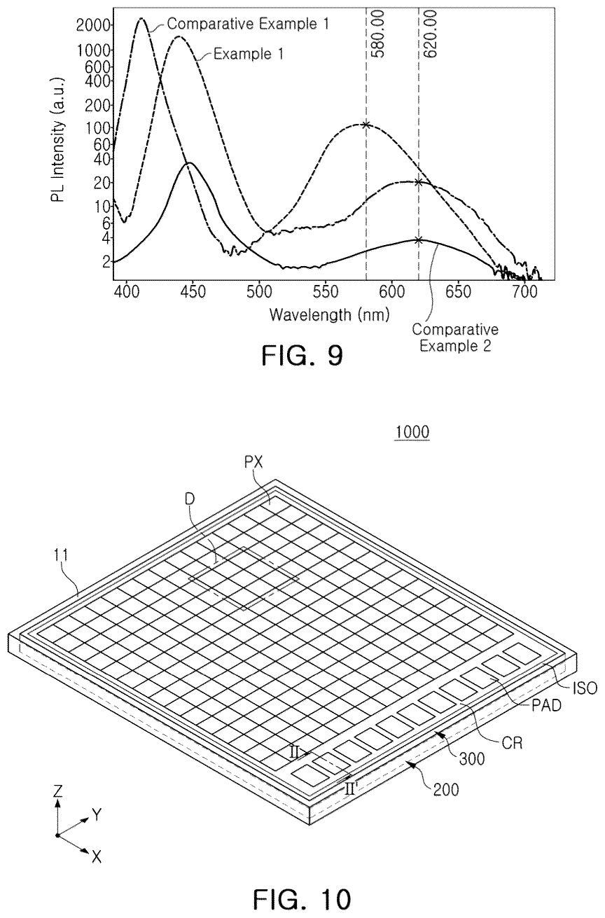

Hereinafter, with reference to FIG. 9, examples of the effects of embodiments of the present disclosure are described in detail.

As illustrated in FIGS. 1 and 2B, a nitride semiconductor light-emitting device may be manufactured according to Example 1.

After forming an N-type GaN layer on a sapphire substrate, an active layer may be formed, and a P-type electron blocking layer and a P-type GaN layer may be formed.

According to Example 1, the active layer may form two stress-relief layers and well layers between three Si-doped GaN barrier layers, according to embodiments described above. For example, a stress-relief layer (having a thickness of about 0.3 nm) and an InGaN well layer (having a thickness of about 5 nm) may be sequentially grown on the barrier layer, the second indium composition ratio x2 of the intermediate layer of the stress-relief layer may be about 0.1, and the first indium composition ratio x1 of the well layer may be about 0.35.

According to embodiments, high-concentration InN structures may be grown on the barrier layer by injecting indium gas and ammonia at a growth temperature of about 650 degrees. InN may not form a layer due to the low growth temperature, and each high-concentration InN structure may have a dome shape with a diameter of 0.5 to 1 nm and a height of 0.5 nm or less, and may be grown to be uniformly dispersed. The intermediate layer may be grown while fixing a plurality of high-concentration InN structures. In this case, the thickness of the intermediate layer may be formed to be 0.3 nm so that it is not larger than the height of the high-concentration InN structures.

According to Comparative Example 1, a nitride semiconductor light-emitting device may be formed to have an active layer without a stress-relief layer in Example 1.

For example, in the semiconductor light-emitting device of Comparative Example 1, two well layers may be placed between the three barrier layers, and the first indium composition ratio x1 of each of the two well layers may be 0.35, which may be the same as Example 1, and the semiconductor light-emitting device may be formed to have a thickness of about 5 nm.

According to Comparative Example 2, a nitride semiconductor light-emitting device may be formed to have an active layer without a stress-relief layer as in Comparative Example 1, and in the semiconductor light-emitting device of Comparative Example 2, two well layers may be formed between three barrier layers. According to Comparative Example 2, to implement a luminescence peak similar to Example 1 according to embodiments, the first indium composition ratio x1 of each of the two well layers may be formed to be 0.50, which may be higher than the indium composition ratio in the example according to embodiments.

FIG. 9 illustrates the emission wavelength and quantum efficiency of Example 1 and Comparative Examples 1 and 2. As shown in FIG. 9, unlike Example 1 according to embodiments, in the case of Comparative Example 1 in which no stress-relief layer exists, the emission wavelength may be about 580 nm, and the emission wavelength may therefore be lengthened by about 40 nm to 620 nm.

Additionally, comparing Example 1 and Comparative Example 2, to lengthen the emission wavelength, the thickness of the well layer may be increased or the indium composition of the well layer may be made larger. Therefore, according to Comparative Example 2, which may induce a similar level of lengthening as Example 1 by greatly increasing the indium composition of the well layer, the quantum efficiency may be significantly reduced.

Therefore, when forming a stress-relief layer as in Example 1 according to embodiments, and maintaining the indium composition ratio of the well layer in the range of 0.3 to 0.5, quantum efficiency may be sufficiently secured while lengthening the wavelength of the emitted red light.

Below, an application example according to embodiments is described with reference to FIGS. 10 to 15.

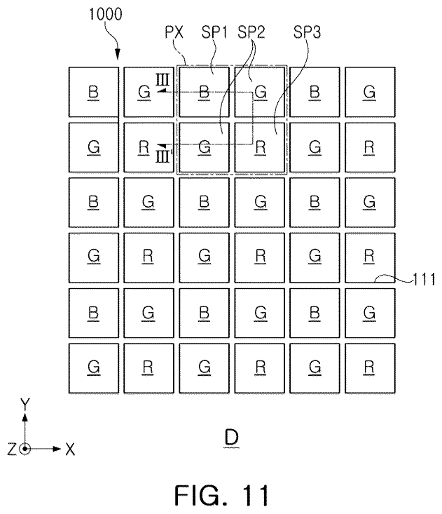

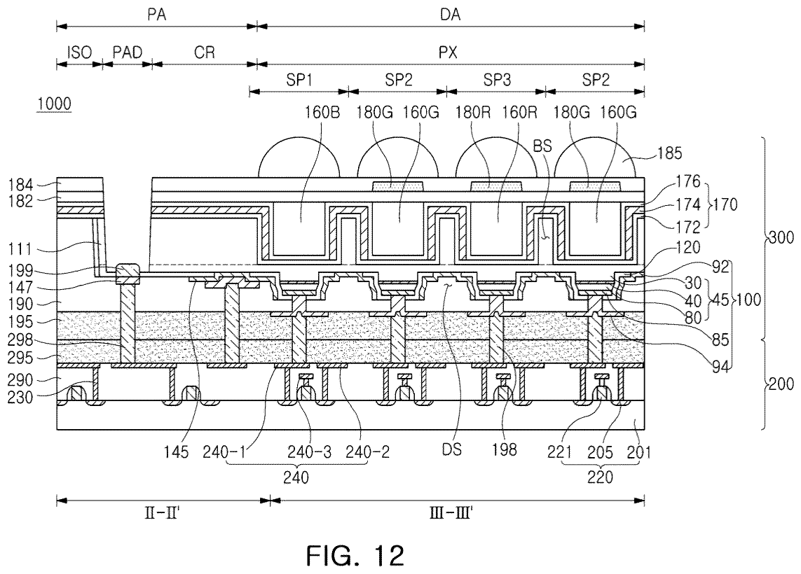

The light-emitting device of the embodiments of FIGS. 1 to 8B may also be used as a light source of a display device. FIG. 10 is a schematic perspective view of a display device according to example embodiments, FIG. 11 is a partially enlarged view illustrating portion “D” of the display device illustrated in FIG. 10, and FIG. 12 is a side cross-sectional view illustrating a display device according to example embodiments.

Referring to FIGS. 10 to 12, a display device 1000 according to embodiments may include a circuit board 200 including driving circuits, and a pixel array 300 disposed on the circuit board 200 and having a plurality of pixels PX arranged therein. The display device 1000 may further include a frame 11 surrounding the circuit board 200 and the pixel array 300.

The circuit board 200 may be a driving circuit board including driving elements 220. In some embodiments, the circuit board 200 may include only some of the driving circuits for the display device, in which case the display device 1000 may further include another driving element. In some embodiments, the circuit board 200 may implement a flexible or curved display device by including a flexible board.

The pixel array 300 may further include connection pads PAD, a connection area (CR) connecting the plurality of pixels PX and the connection pads PAD, and an edge area (ISO), in addition to the plurality of pixels PX.

Each of the plurality of pixels PX may include first to third sub-pixels SP1, SP2 and SP3 configured to emit light of a specific wavelength, for example, a specific color, to provide a color image. For example, the first to third subpixels SP1, SP2, and SP3 may be configured to emit blue (B) light, green (G) light, and red (R) light, respectively. In each pixel PX, the first to third subpixels SP1, SP2, and SP3 may be arranged in, for example, a Bayer pattern. In detail, each pixel PX may include first and third subpixels SP1 and SP3 arranged in the first diagonal direction, and two second subpixels SP2 arranged in a second diagonal direction intersecting the first diagonal direction.

The X-direction and Y-direction may be perpendicular to each other and parallel to the upper surface of the display device 1000. The Z-direction may be a direction perpendicular to the X- and Y-directions, for example, a direction perpendicular to the upper surface of the display device 1000.

In the example shown in FIG. 10, each pixel PX is illustrated as having first to third subpixels SP1, SP2, and SP3 arranged in a 2≤2 Bayer pattern, but embodiments are not limited thereto. For example, in some embodiments, each pixel PX may be configured in a different arrangement, such as 3×3 or 4×4. Additionally, in some embodiments, some sub-pixels may be configured to emit light in a color other than the illustrated colors (R, G, B), such as yellow light. In the pixel array 300 of FIG. 10, the plurality of pixels PX are illustrated in a 15×15 array that is a relatively small number of pixels for convenience of explanation, but depending on the actual application product, and the size of rows and columns increases. For example, for application thereof to a high-resolution display, it needs to be implemented in an array such as 1,920×1,080 (FHD), 3,840×2,160 (UHD), or the like. In the case of a smart watch, the plurality of pixels PX has an array of around 400×400. Depending on the size of the display device, the pixel size and unit LED element size vary. For example, assuming a display device for tablets, smartphones, and VR devices with vertical sizes of 152.4 mm, 50.8 mm, and 38.1 mm, various pixel densities ranging from 180 ppi to 1,440 ppi may be required. At the same time, a light-emitting device with sufficient luminous efficiency is required. For this application, embodiments may provide a light-emitting device 100 having improved luminous efficiency and a size of 200 μm or less. For example, the light-emitting device 100 may have a size of 20 μm or less. As another example, the light-emitting device 100 may have a size of 5 nm or more. Additionally, the distance between adjacent light-emitting devices 100 disposed in the display device 1000 according to embodiments may be in a range of 5 nm to 100 μm.

The connection pads PAD may be disposed on at least one side of the plurality of pixels PX along the edge of the display device 1000. The connection pads PAD may be electrically connected to the plurality of pixels PX and the driving circuits of the circuit board 200. Connection pads PAD may electrically connect an external device and the display device 1000. In some embodiments, the number of connection pads PAD may vary and may be determined, for example, depending on the number of pixels PX, the driving method of the driving circuit in the circuit board 200, etc.

The connection area CR may be an area located between the plurality of pixels PX and the connection pads PAD. An interconnection structure, such as a common electrode, which is electrically connected to the plurality of pixels PX may be disposed in the connection region CR.

The edge area ISO may be an area along the edges of the pixel array 300. The frame 11 may be arranged around the pixel array 300 and serve as a guide for defining the arrangement space of the pixel array 300. Frame 11 may include at least one of materials such as polymer, ceramic, semiconductor, or metal, for example.

Referring to FIG. 12, the display device 1000 may include a circuit board 200 and a pixel array 300 disposed on the circuit board 200.

The circuit board 200 may include a semiconductor substrate 201, a driving circuit including driving elements 220 formed on a semiconductor substrate 201, interconnections 230 electrically connected to the driving elements 220, interconnection lines 240 on the interconnects 230, and a first interconnection insulating layer 290 covering the driving circuit. The circuit board 200 may further include a first bonding insulating layer 295 on the first interconnection insulating layer 290, and first bonding electrodes 298 disposed in the first bonding insulating layer 295 and connected to the interconnection lines 240.

The semiconductor substrate 201 may include impurity regions including source/drain regions 205. The semiconductor substrate 201 may include, for example, a semiconductor such as silicon (Si) or germanium (Ge), or a compound semiconductor such as SiGe, SiC, GaAs, InAs, or InP.

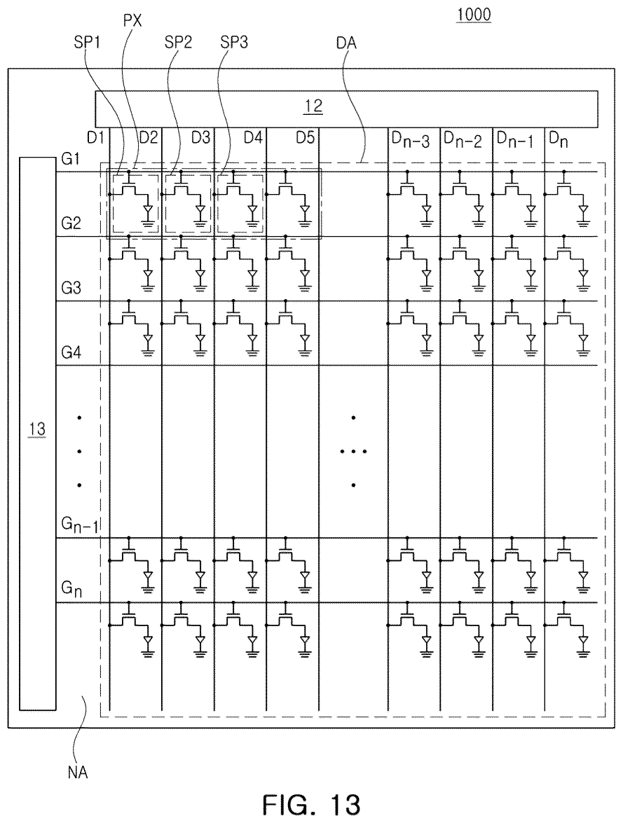

The driving circuit may include a circuit for controlling driving of a pixel, particularly a sub-pixel. The source region 205 of the driving elements 220 may be electrically connected to one electrode of the light-emitting stacks 45 through the interconnection 230, the interconnection line 240, and the first bonding electrode 298. For example, the drain region 205 of the driving elements 220 may be connected to the data lines D1, D2, . . . , Dn through the interconnector 230 and the interconnection line 240. The gate electrodes 221 of the driving elements 220 may be connected to the gate lines G1, G2, . . . , Gn through the interconnector 230 and the interconnection line 240. This circuit configuration and operation will be described in more detail with reference to FIG. 13 below.

The upper surfaces of the first bonding electrodes 298 and the upper surfaces of the first bonding insulating layer 295 may form the upper surface of the circuit board 200. The first bonding electrodes 298 may be bonded to the second bonding electrodes 198 of the pixel array 300 to provide an electrical connection path. The first bonding electrodes 298 may include a conductive material, for example, copper (Cu). The first bonding insulating layer 295 may be bonded to the second bonding insulating layer 195 of the pixel array 300. The first bonding insulating layer 295 may include, for example, at least one of SiO, SiN, SiCN, SiOC, SiON, and SiOCN.

The pixel array 300 may include a plurality of light-emitting devices 100 arranged one for each subpixel SP1, SP2, and SP3. The light-emitting device 100 may use the light-emitting device 100 of the embodiments described in FIGS. 1 to 8B. At least some of the first electrodes 92 and second electrodes 94 of the plurality of light-emitting devices 100 may be connected to each other and formed as one body.

The pixel array 300 may include a plurality of light-emitting stacks 45, a passivation layer 120 covering each side of the light-emitting stacks 45, and first and second electrodes 92 and 94 electrically connected to the light-emitting stacks 45. The pixel array 300 may include wavelength conversion units 160R, 160G, and 160B, color filters 180R and 180G, and micro lenses 185 on the light-emitting stacks 45. The pixel array 300 may further include a barrier structure BS that surrounds the sides of the wavelength conversion units 160R, 160G, and 160B and separates the wavelength conversion units from each other. Additionally, the pixel array 300 may further include a sealing layer 182 and a planarization layer 184 on the wavelength conversion units 160R, 160G and 160B, a common electrode 145, a first pad electrode 147, a second interconnection insulating layer 190, a second bonding insulating layer 195, second bonding electrodes 198, and a second pad electrode 199.

The light-emitting stacks 45 include second conductivity-type nitride semiconductor layers 80 (e.g., P-type nitride semiconductor layers), first conductivity-type nitride semiconductor layers 30 (e.g., N-type nitride semiconductor layers), and active layers 40 disposed therebetween, and the first electrode 92 may be electrically connected to the first conductivity-type nitride semiconductor layer 30 and the second electrodes 94 are electrically connected to the second conductivity-type nitride semiconductor layer 80. The passivation layer 120 may extend to the lower surface of the light-emitting stacks 45, and the second electrodes 94 may penetrate the passivation layer 120 and be connected to the second conductivity-type nitride semiconductor layers 80.

The pixel array 300 may further include P-type contact electrodes 85 that contact the entire lower surface of each of the second conductivity-type nitride semiconductor layers 80. At this time, the passivation layer 120 may extend to the lower surface of the light-emitting stacks 45 while covering the P-type contact electrodes 85. The second electrodes 94 may contact the P-type contact electrodes 85. The P-type contact electrodes 85 may have a thicker central portion than the peripheral portion.

The wavelength conversion units 160R, 160G, and 160B may be respectively disposed on the light-emitting stacks 45. The wavelength conversion units 160R, 160G and 160B may respectively be areas in which wavelength conversion materials such as quantum dots are dispersed in liquid binder resin and filled and cured within the barrier structure BS. The first wavelength conversion unit 160R and the second wavelength conversion unit 160G may include quantum dots capable of converting blue light into red light and green light, respectively, and the third wavelength conversion unit 160B may form a transparent resin unit by containing only binder resin without separate quantum dots.

The barrier wall reflection layers 170 may be disposed within the barrier structure BS to surround the side surfaces and lower surfaces of the wavelength conversion units 160R, 160G, and 160B. The barrier wall reflection layers 170 may include a first barrier rib insulating layer 172, a barrier metal layer 174, and a second barrier rib insulating layer 176, respectively, arranged sequentially from the bottom. The barrier metal layer 174 may be disposed only on the side surfaces of the wavelength conversion units 160R, 160G, and 160B, and may not be disposed under the lower surfaces. The lower surfaces of the barrier wall reflection layers 170 may be located at a higher level than the uppermost surface of the first electrode 92. The first barrier rib insulating layer 172 and the second barrier rib insulating layer 176 may include an insulating material, for example, at least one of SiO₂, SiN, SiCN, SiOC, SiON, and SiOCN. The barrier metal layer 174 may include a reflective metal, for example, at least one of silver (Ag), nickel (Ni), and aluminum (Al).

The sealing layer 182 may be arranged to cover the upper surfaces of the wavelength conversion units 160R, 160G, and 160B. The sealing layer 182 may function as a protective layer that prevents deterioration of the wavelength conversion units 160R, 160G, and 160B. In some embodiments, sealing layer 182 may be omitted.

The color filters 180R and 180G may be disposed in the second and third subpixels SP2 and SP3 and on the wavelength conversion units 160R, 160G, and 160B. The color filters 180R and 180G may increase the color purity of light emitted through the first wavelength conversion unit 160R and the second wavelength conversion unit 160G. In some embodiments, a color filter may be further disposed on the third wavelength conversion unit 160B.

The planarization layer 184 may be disposed to cover the upper surfaces of the color filters 180R and 180G and the sealing layer 182. The planarization layer 184 may be a transparent layer.

The micro lenses 185 may be arranged to correspond to the wavelength conversion units 160R, 160G, and 160B on the planarization layer 184, respectively. The micro lenses 185 may converge light incident from the wavelength conversion units 160R, 160G, and 160B. For example, the micro lenses 185 may have a diameter larger than the width of the light-emitting stacks 45 in the X and Y-directions. The micro lenses 185 may be formed of, for example, a transparent photoresist material or a transparent thermosetting resin film.

The light-emitting stack 45 may be formed by depositing on the substrate 10 using a method such as metal organic chemical vapor deposition (MOCVD). In embodiments, the substrate 10 may be, for example, a growth substrate. When using a substrate 10 made of a different material from the light-emitting stack 45, after forming the buffer layer 20 on the substrate 10, a light-emitting stack 45 may be formed on the buffer layer 20. The light-emitting stack 45 may be made of a nitride semiconductor containing Ga.

The substrate 10 and the buffer layer 20 may be partially or completely removed during the manufacturing process of the light-emitting device 100. Accordingly, the light-emitting device 100 may further include a substrate 10, and may further include a buffer layer 20 between the substrate 10 and the light-emitting stack 45. In some cases, only a portion of the buffer layer 20 may be further included without the substrate 10.

To create the pixel array 300, a buffer layer 20 is formed on the substrate 10, in the same manner as the light-emitting device 100 of FIG. 1, and after forming the light-emitting stack 45 by sequentially stacking the first conductivity-type nitride semiconductor layer 30, the active layer 40, and the second conductivity-type nitride semiconductor layer 80 on the buffer layer 20, the light-emitting stack 45 in the device isolation region DS is removed from the direction of the second conductivity-type nitride semiconductor layer 80 to create a plurality of light-emitting stacks 45. Additionally, some or all of the substrate 10 and the buffer layer 20 may be removed from the substrate direction. According to embodiments, the grooves for arranging the wavelength conversion units 160R, 160G, and 160B in the window regions corresponding to each of the light-emitting stacks 45 are etched away and removed. A barrier rib structure BS including a barrier rib disposed on the device isolation region DS is formed. In the window area where the wavelength conversion units 160R, 160G, and 160B will be installed, the substrate 10 may be completely removed, and a portion or entirety of the buffer layer 20 may be removed. Part or all of the substrate 10 and the buffer layer 20 may be removed from the portion corresponding to the partition on the device isolation region DS. When the substrate 10 is not completely removed, the barrier structure BS of the pixel array 300 includes the substrate 10 and may further include a portion of the buffer layer 20.

FIG. 13 is a driving circuit implemented in a display device according to example embodiments.

Referring to FIG. 13, a circuit diagram of a display device 1000 in which N×N subpixels are arranged is illustrated. The first to third subpixels SP1, SP2, and SP3 may each receive data signals through data lines D1-Dn, which are vertical paths, for example, column directions. The first to third subpixels SP1, SP2, and SP3 may receive a control signal, for example, a gate signal, through the gate lines G1-Gn, which are horizontal paths, for example, in the row direction.

A plurality of pixels PX including the first to third sub-pixels SP1, SP2 and SP3 provide an active area da for display, and this active area da serves as a display area for the user. The non-active area NA may be formed along one or more edges of the active area da. The inactive area NA may extend along the outer periphery of the panel of the display device 1000, may be an area in which pixels PX do not exist, and may correspond to the frame 11 (see FIG. 10) of the display device 1000.

The first and second driver circuits 12 and 13 may be employed to control the operation of the pixels PX, for example, the first to third subpixels SP1, SP2, and SP3. Some or all of the first and second driver circuits 12 and 13 may be implemented on the circuit board 200. The first and second driver circuits 12 and 13 may be formed of an integrated circuit, a thin film transistor panel circuit, or other suitable circuit, and may be disposed in the non-active area NA of the display device 1000. The first and second driver circuits 12 and 13 may include a microprocessor, memory such as storage, processing circuitry, and communication circuitry.

To display an image by pixels PX, the first driver circuit 12 supplies image data to the data lines D1-Dn and provides a clock signal to the second driver circuit 13, which is a gate driver circuit. and other control signals. The second driver circuit 13 may be implemented using an integrated circuit and/or a thin film transistor circuit. A gate signal for controlling the first to third subpixels SP1, SP2, and SP3 arranged in the row direction may be transmitted through the gate lines G1-Gn of the display device 1000.

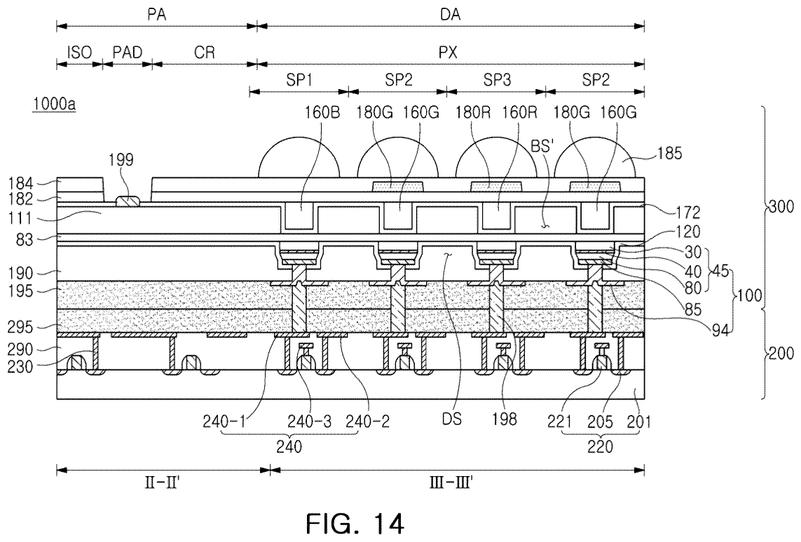

FIG. 14 is a side cross-sectional view illustrating a display device according to example embodiments.

Referring to FIG. 14, a display device 1000a may include a circuit board 200 and a pixel array 300 disposed on the circuit board 200, and may include many of the same components as those of the display device 1000 described with reference to FIG. 12. However, the display device 1000A according to the present embodiment may have a barrier structure BS' and an interconnection structure that are different from the barrier structure BS and the resulting interconnection structure shown in FIG. 1.

According to embodiments, the pixel array 300 may include a barrier structure BS' formed separately from the light-emitting stacks 45. The barrier rib structure BS' may include a conductive material and may simultaneously act as part of the first electrode structure. In this case, the barrier structure BS' may be arranged between each light-emitting stack 45 to overlap a portion of the peripheral area of the light-emitting stack 45 in the Z-axis direction.

The barrier structure BS' may be connected to each first conductivity-type nitride semiconductor layer 30 of the light-emitting stack 45 through the N-type contact electrode 83. The N-type contact electrode 83 may be made of a transparent conductive material such as ITO, and may be in direct contact with the first conductivity-type nitride semiconductor layer 30 without the N-type contact electrode 83. The barrier structure BS may be formed of a highly reflective material such as Ag or the like, and the first barrier wall insulating layer 172 surrounding the sides of the wavelength conversion units 160R, 160G, and 160B may be disposed on a barrier structure BS. The pixel array 300 may include a second pad electrode 199 formed on an exposed area of the barrier structure BS.

The display devices 1000 and 1000a of FIGS. 10 to 14 in example embodiments may be full-color monolithic display devices including a light-emitting device array formed at the wafer level, and may be characterized by forming a light-emitting device array at the wafer level without a pick-and-place process for individual chips of the individual light-emitting devices 100, thereby increasing the density between light-emitting devices. The width of the device isolation area for separating light-emitting devices on the wafer becomes the gap between the light-emitting devices 100 in the light-emitting device 100.

The display device according to embodiments is not limited to the particular display devices 1000 and 1000a described above, and some configurations may be excluded or modified. For example, a single-color monolithic display device may be configured excluding the wavelength conversion units 160B, 160G, and 160R or the color filters 180R and 180G. The display device 1000 may be formed by moving the light-emitting device 100 on a circuit board using a pick-and-place method. The light-emitting devices 100, 100a, 100b, 100c, and 100d of the embodiments of FIGS. 1 to 8B are arranged in an array form, and are combined with a substrate including a driving element, thereby forming the display device 1000 of an example embodiment.

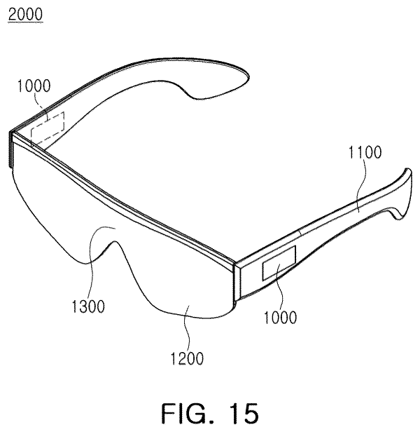

FIG. 15 is a schematic diagram of an electronic device including a display device according to example embodiments.

Referring to FIG. 15, an electronic device 2000 may be a glasses-type display, which may be a wearable device. The electronic device 2000 may include a pair of temples 1100, a pair of optical coupling lenses 1200, and a bridge 1300. The electronic device 2000 may further include a display device 1000 including an image generator.

The electronic devices 2000 may be a head-mounted, glasses-type, or goggle-type virtual reality (VR) device or an augmented reality (AR) device, or a mixed reality (MR) device, which may provide virtual reality or provide both virtual images and actual external scenery.

The temples 1100 may extend in one direction. The temples 1100 may be spaced apart from each other and extend in parallel. The temples 1100 may be folded toward the bridge 1300. The bridge 1300 may be provided between the optical coupling lenses 1200 to connect the optical coupling lenses 1200 to each other. The optical coupling lenses 1200 may include a light guide plate. The display device 1000 may be disposed on each of the temples 1100 and may generate images on the optical coupling lenses 1200. The display device 1000 may be a display device according to the embodiments described above with reference to FIGS. 1 to 14.

As set forth above, in a nitride semiconductor light-emitting device according to the above-described embodiments, stress generation within the active layer may be suppressed by introducing a plurality of stress-relief layers, and by introducing InN clusters into the stress-relief layer, the wavelength of red light generated in the well layer may be shifted to the long wavelength side to emit red light with a longer wavelength. Therefore, a nitride semiconductor light-emitting device emitting long-wavelength light with relatively high internal quantum efficiency may be provided.

While example embodiments are illustrated and described above, it will be apparent to those skilled in the art that modifications and variations may be made without departing from the scope of the present disclosure.

What is claimed is:

1. A nitride semiconductor light-emitting device comprising:
a P-type nitride semiconductor layer;
an N-type nitride semiconductor layer;
an InGaN well layer between the P-type nitride semiconductor layer and the N-type nitride semiconductor layer;
a barrier layer having a bandgap wider than the InGaN well layer; and
a stress-relief layer between the barrier layer and the InGaN well layer,
wherein the stress-relief layer comprises a plurality of InN structures spaced apart from each other and distributed on the barrier layer.

2. The nitride semiconductor light-emitting device of claim 1, wherein a thickness of the stress-relief layer is less than a thickness of the InGaN well layer.

3. The nitride semiconductor light-emitting device of claim 1, wherein a thickness of the stress-relief layer is less than 1 nanometer (nm).

4. The nitride semiconductor light-emitting device of claim 1, wherein the plurality of InN structures are distributed on the barrier layer in an island type arrangement.

5. The nitride semiconductor light-emitting device of claim 4, wherein each InN structure from among the plurality of InN structures is shaped as a portion of a sphere with a surface in contact with the barrier layer, and
wherein a first diameter of the surface is within a range of 0.5 nanometers (nm) to 1.0 nm.

6. The nitride semiconductor light-emitting device of claim 5, wherein each InN structure is spaced apart from neighboring InN structures by at least a minimum separation distance.

7. The nitride semiconductor light-emitting device of claim 6, wherein the minimum separation distance is 1 to 1.5 times the first diameter of the plurality of InN structures.

8. The nitride semiconductor light-emitting device of claim 1, wherein the stress-relief layer comprises an InGaN intermediate layer configured to fix the plurality of InN structures on the barrier layer, and
wherein an indium concentration of the InGaN intermediate layer is lower than an indium concentration of the InGaN well layer.

9. The nitride semiconductor light-emitting device of claim 8, wherein a thickness of the InGaN intermediate layer is substantially equal to or smaller than a height of the plurality of InN structures.

10. The nitride semiconductor light-emitting device of claim 8, wherein as an indium composition of the InGaN intermediate layer decreases, a thickness of the InGaN intermediate layer increases.

11. The nitride semiconductor light-emitting device of claim 10, wherein an upper surface of the InGaN intermediate layer is above a midpoint of a height of a plurality of the InN structures.

12. The nitride semiconductor light-emitting device of claim 11, wherein the InGaN well layer comprises a first nitride single crystal represented by Inₓ₁Ga₁₋ₓ₁N, where x1 denotes a first indium composition ratio, and wherein the first indium composition ratio is in a range of 0.3 to 0.5, and
wherein the InGaN intermediate layer comprises a second nitride single crystal represented by Inₓ₂Ga₁₋ₓ₂N, where x2 denotes a second indium composition ratio, and
wherein the second indium composition ratio is in a range of 0 to 0.1.

13. The nitride semiconductor light-emitting device of claim 12, wherein the nitride semiconductor light-emitting device is configured to emit light have a peak wavelength in a range of 620 nanometers (nm) to 650 nm.

14. The nitride semiconductor light-emitting device of claim 1, wherein the InGaN well layer has a thickness of 2 nanometers (nm) to 5 nm,
the barrier layer has a thickness of 5 nm to 20.0 nm, and
the stress-relief layer has a thickness of 0.15 nm to 0.5 nm.

15. A nitride semiconductor light-emitting device comprising:
a P-type nitride semiconductor layer;
an N-type nitride semiconductor layer; and
an active layer between the P-type nitride semiconductor layer and the N-type nitride semiconductor layer,
wherein the active layer comprises:
a plurality of GaN barrier layers;
a plurality of InGaN well layers disposed between the plurality of GaN barrier layers; and
a plurality of stress-relief layers disposed between the plurality of GaN barrier layers and the plurality of InGaN well layers,
wherein the plurality of stress-relief layers comprise a plurality of InN structures distributed on the plurality of GaN barrier layers, and a plurality of InGaN intermediate layers between the plurality of InN structures on the plurality of GaN barrier layers,
wherein an indium concentration of the plurality of InGaN intermediate layers is lower than an indium concentration of the plurality of InGaN well layers, and
wherein a thickness of the plurality of InGaN intermediate layers is less than a thickness of the plurality of InGaN well layers.

16. The nitride semiconductor light-emitting device of claim 15, wherein an indium composition of the plurality of InGaN intermediate layers decreases as a distance from an upper surface of the N-type nitride semiconductor layer increases.

17. The nitride semiconductor light-emitting device of claim 16, wherein a thickness of the plurality of InGaN intermediate layers increases, as the distance from the upper surface of the N-type nitride semiconductor layer increases.

18. The nitride semiconductor light-emitting device of claim 16, wherein the plurality of InGaN well layers comprise first nitride single crystals represented by Inₓ₁Ga₁₋ₓ₁N, where x1 denotes a first indium composition ratio, and wherein the first indium composition ratio is in a range of 0.3 to 0.5, and
wherein the plurality of InGaN intermediate layers comprise second nitride single crystals represented by Inₓ₂Ga₁₋ₓ₂N, where x2 denotes a second indium composition ratio, and wherein the first indium composition ratio is in a range of 0 to 0.1.

19. The nitride semiconductor light-emitting device of claim 18, wherein the second indium composition ratio of a lowermost InGaN intermediate layer from among the plurality of InGaN intermediate layers has is in a range of 0.05 to 0.1, and
wherein the second indium composition ratio of remaining InGaN intermediate layers from among the plurality of InGaN intermediate layers is substantially equal to 0.

20. A display device comprising:
a circuit board comprising a plurality of driving elements; and
a pixel array disposed on the circuit board and comprising a plurality of light-emitting devices,
wherein each light-emitting device from among the plurality of light-emitting devices comprises:
a P-type nitride semiconductor layer;
an N-type nitride semiconductor layer; and
an active layer between the P-type nitride semiconductor layer and the N-type nitride semiconductor layer,
wherein the active layer comprises:
a plurality of GaN barrier layers;
a plurality of InGaN well layers disposed between the plurality of GaN barrier layers; and
a plurality of stress-relief layers disposed between the plurality of GaN barrier layers and the plurality of InGaN well layers,
wherein the plurality of stress-relief layers comprise a plurality of InN structures distributed on the plurality of GaN barrier layers and a plurality of InGaN intermediate layers between the plurality of InN structures on the plurality of GaN barrier layers,
wherein an indium concentration of the plurality of InGaN intermediate layers is lower than an indium concentration the plurality of InGaN well layers, and
wherein a thickness of the plurality of InGaN intermediate layers is less than a thickness of the plurality of InGaN well layers.
